(19) United States
(12) Patent Application Publication
(10) Pub. No.: US 2021/0340444 A1
(43) Pub. Date: Nov. 4, 2021

(54) SINGLE CRYSTALLINE PHOSPHOR AND METHOD FOR PRODUCING CRYSTAL BODY

(71) Applicant: TDK CORPORATION, Tokyo (JP)

(72) Inventor: Tatsuya TERUI, Tokyo (JP)

(73) Assignee: TDK CORPORATION, Tokyo (JP)

(21) Appl. No.: 17/240,370

(22) Filed: Apr. 26, 2021

(30) Foreign Application Priority Data
Apr. 30, 2020 (JP) 2020-080508

(51) Int. Cl. C09K 11/77; C30B 15/08; H01L 33/50

(52) U.S. Cl. CPC C09K 11/7715; H01L 33/50; C30B 15/08

(57) ABSTRACT

Provided is a method for producing a crystal body that can obtain a crystal body having a relatively large size and a more uniform composition, and a novel single crystalline phosphor obtained by the above producing method. The single crystalline phosphor contains YAG or LuAG as a main component and at least one element of Ce, Pr, Sm, Eu, Tb, Dy, Tm, and Yb as an accessory component. In a cross section of the single crystalline phosphor, a uniform concentration region in which the accessory component is uniformly distributed is located in a central portion of the cross section, and an area ratio of the uniform concentration region to a cross-sectional area of the cross section is 35% or more.

### BACKGROUND OF THE INVENTION

### Field of the Invention

The present invention relates to a method for producing a crystal body using, for example, a micro-pulling down method (hereinafter referred to as μ-PD method), and a single crystalline phosphor obtained by the method.

### Description of the Related Art

Applications of a single crystalline phosphor as a color tone conversion material for lighting and projectors using LEDs and lasers have been investigated. In these applications, if brightness and fluorescence chromaticity vary in a plane of the single crystalline phosphor, required characteristics as a device cannot be obtained.

A phosphor is imparted with fluorescence characteristics by replacing some elements of a host structure crystal (main component) with other elements (additive/accessory component). However, in the case of the single crystalline phosphor, since segregation of additives occurs during crystal growth, a concentration distribution of the additives occurs in a crystal plane, resulting in variations in the brightness and the fluorescence chromaticity.

There is an attempt to produce such a single crystalline phosphor by a μ-PD method. In the μ-PD method, a melt of a single crystal material flowing out from a pore of a crucible comes into contact with a seed crystal arranged below the pore, and a desired single crystal grows on the seed crystal as the melt cools. By pulling down a seed crystal holder that holds the seed crystal according to a growth rate of the single crystal, the single crystal can be grown in a pulling down direction of the seed crystal.

As the crucible used in the μ-PD method, for example, a crucible shown in Patent Literature 1 (JP-A-2005-35861) is known. In the crucible shown in Patent Literature 1, by devising a shape of an outer bottom surface of the crucible, increasing the number of pores, providing an after-heater, and the like, attempts have been made to achieve uniformity of a temperature distribution of the melt drawn by the seed crystal and to obtain a crystal having a uniform composition.

However, it is difficult to sufficiently achieve uniformity of a temperature distribution of the melt drawn by the seed crystal by a method for producing a crystal body using the crucible in the related art, and it is difficult to obtain a crystal body, particularly a single crystalline phosphor, including a uniform composition region having a relatively large area in a cross section.

### SUMMARY OF THE INVENTION

The present invention is made in view of such a circumstance and an object thereof is to provide a crystal body having a more uniform composition and to provide a method for producing a crystal body by which the crystal body can be obtained.

In order to achieve the above object, a method for producing a crystal body according to the present invention includes the steps of:

guiding a melt of a raw material of the crystal body, from a melt storage portion of a crucible to a die flow path;

passing the melt guided to the die flow path through a narrow portion provided in the die flow path;

passing the melt through a divergent portion whose flow path cross-sectional area increases from the narrow portion toward a die outlet; and

pulling down the melt that passed through the divergent portion from the die outlet together with a seed crystal so as to crystallize the melt.

As a result of earnest investigation, the present inventor has found that uniformity of a temperature distribution of the melt drawn by the seed crystal (particularly uniformity of the temperature distribution at a solid-liquid interface along a plane perpendicular to a drawing direction of the melt) can be achieved by providing the narrow portion in a middle of the die flow path when passing the melt from the melt storage portion to the die flow path of the crucible, so that a crystal body, particularly a single crystalline phosphor, including a uniform composition region having a relatively large area in a cross section can be obtained. Thus, the present invention has been completed.

Preferably, the die flow path includes the divergent portion whose flow path cross-sectional area increases from the narrow portion toward the die outlet along a pulling down direction of the melt. With such a configuration, the uniformity of the temperature distribution of the melt drawn by the seed crystal and uniformity of a composition of an obtained crystal are improved.

The die flow path may include an introduction portion whose inlet is a storage portion outlet and a flow path main body portion communicating with the introduction portion, and it is preferable that an outlet of the flow path main body portion is the die outlet. The die flow path may not include the introduction portion and may include only the flow path main body portion, but it is preferable that the die flow path includes the introduction portion.

The introduction portion may have a flow path cross-sectional area that changes along a flow direction, but preferably, the introduction portion is a straight body portion having a substantially constant flow path cross-sectional area along the flow direction of the melt. The term “substantially constant” means that the cross-sectional area may be changed to some extent, and the cross-sectional area is less changed than the divergent portion formed at the flow path main body portion. In the introduction portion, a flow path may be slightly expanded or slightly narrowed from the storage portion outlet toward the flow path main body portion.

Preferably, the narrow portion is formed at the introduction portion (including the storage portion outlet, a middle of the introduction portion, or a boundary between the introduction portion and the flow path main body portion). When the introduction portion is a straight body portion, the narrow portion is formed at a middle of the straight body portion, the storage portion outlet, or the boundary between the introduction portion and the flow path main body portion. Since the narrow portion is formed at the introduction portion, it becomes easy to adjust a flow rate of the melt stored in the storage portion passing through the die flow path, the melt can be drawn from the die outlet at a stable speed, and the uniformity of the composition of the crystal (the uniformity in the drawing direction) is improved.

The narrow portion may be formed at the flow path main body portion. When the narrow portion is formed at the flow path main body portion, the divergent portion whose flow path cross-sectional area increases from the narrow portion toward the die outlet is formed. An intermediate-expanded portion having a larger cross-sectional area than the introduction portion and the narrow portion may be formed between the narrow portion formed at the flow path main body portion and the introduction portion.

Preferably, a ratio (S2/S1) of an opening area (S2) of the die outlet to a flow path cross-sectional area (S1) of the narrow portion is 3 to 3000. Within such a range, the uniformity of the temperature distribution of the melt drawn by the seed crystal and the uniformity of the composition of the obtained crystal are improved.

Preferably, a flat end peripheral surface that is substantially perpendicular to the drawing direction of the melt is provided at an end surface of a die portion around the die outlet. With such a configuration, an outer peripheral surface shape of the crystal obtained by using the crucible can be easily controlled.

A ratio (S2/(S2+S3)) of the opening area (S2) of the die outlet to a sum of the opening area (S2) of the die outlet and an area (S3) of the end peripheral surface is preferably 0.1 to 0.95. With such a configuration, the uniformity of the temperature distribution of the melt drawn by the seed crystal and the uniformity of the composition of the obtained crystal are further improved.

A single crystalline phosphor according to the present invention is a single crystalline phosphor containing: a main component comprised of YAG or LuAG; and an accessory component including at least one of Ce, Pr, Sm, Eu, Tb, Dy, Tm, and Yb, in which

a uniform concentration region in which the accessory component is uniformly distributed is located in a central portion of a cross section of the single crystalline phosphor, and

an area ratio of the uniform concentration region to the cross section is 35% or more.

According to the single crystalline phosphor of the present invention, it is possible to reduce thermal energy loss when excitation light is converted into fluorescence, and to increase energy efficiency (an amount of light emitted with respect to input power) of an entire device, and fluorescence conversion efficiency is improved. According to the single crystalline phosphor of the present invention, it is possible to reduce a variation in brightness.

Preferably, the uniform concentration region exists continuously and independently in the cross section. With such a single crystalline phosphor, the variation in the brightness can be further reduced and the energy efficiency of the entire device can be increased.

Preferably, an average concentration of the accessory component is 0.7 atomic % or more, and more preferably 1.0 atomic % or more in the uniform concentration region in the cross section. Preferably, a fluctuation range of a concentration of the accessory component is within a range of ±0.07 atomic % in the uniform concentration region. Preferably, the main component is comprised of YAG and the accessory component is comprised of Ce. The concentration of the accessory component in the uniform concentration region is preferably 0.7 (±0.07) atomic % or more, and more preferably 1.0 (±0.07) atomic % or more. A single crystalline phosphor including such a uniform concentration region having an area ratio of a predetermined value or more and having the concentration of the accessory component cannot be obtained in the related art.

### BRIEF DESCRIPTION OF THE DRAWINGS

FIG. 1 is a schematic cross-sectional view of a crystal growth equipment used in a method for producing a crystal body according to an embodiment of the present invention.

FIG. 2A is an enlarged cross-sectional view of a part II of the crystal growth equipment shown in FIG. 1.

FIG. 2A1 is an enlarged cross-sectional view of a die portion shown in FIG. 2A.

FIG. 2B is an enlarged cross-sectional view of a crystal growth equipment according to another embodiment of the present invention.

FIG. 2C is an enlarged cross-sectional view of a crystal growth equipment according to still another embodiment of the present invention.

FIG. 2D is an enlarged view of a crystal growth equipment according to a fourth embodiment, which is another modification of FIG. 2A.

FIG. 3A is an arrow view of the die portion shown in FIG. 2A along a line III-III.

FIG. 3B is a schematic view showing a temperature distribution of a melt immediately after being drawn from the die portion by a method for producing a crystal body according to Examples of the present invention.

FIG. 3C is a schematic view showing a concentration distribution of Ce in a cross section of Ce:YAG as a single crystalline phosphor according to Examples of the present invention.

FIG. 3D is a graph showing a concentration distribution of Ce in a cross section along a line IIID-IIID shown in FIG. 3C.

FIG. 3E is a schematic view showing a method of measuring a light ratio in Examples of the present invention.

FIG. 4 is an enlarged cross-sectional view of a die portion used in a method for producing a crystal body according to Comparative Example of the present invention.

FIG. 5A is an arrow view along a line V-V shown in FIG. 4.

FIG. 5B is a schematic view showing a temperature distribution of a melt immediately after being drawn from the die portion using a method for producing a crystal body according to Comparative Example.

FIG. 5C is a schematic view showing a concentration distribution of Ce in a cross section of Ce:YAG produced by using the method for producing a crystal body according to Comparative Example.

### DETAILED DESCRIPTION OF THE PREFERRED EMBODIMENTS

Hereinafter, the present invention will be described based on embodiments shown in the drawings.

### First Embodiment

First, a crystal growth equipment used in a method for producing a crystal body according to an embodiment of the present invention will be described.

(Crystal Growth Equipment)

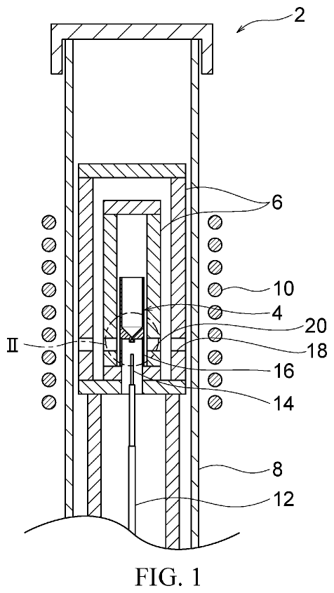

As shown in FIG. 1, a crystal growth equipment 2 according to the present embodiment includes a crucible 4 and refractory furnaces 6. The crucible 4 will be described later. The refractory furnaces 6 cover a periphery of the crucible 4 doubly. The refractory furnaces 6 are formed with observation windows 18, 20 for observing a pulling down state of a melt from the crucible 4.

The refractory furnaces 6 are further covered with an outer casing 8, and a main heater 10 for heating the entire crucible 4 is provided on an outer periphery of the outer casing 8. In the present embodiment, the outer casing is formed by, for example, a quartz tube, and an induction heating coil 10 is used as the main heater 10. A seed crystal 14 held by a seed crystal holding jig 12 is arranged below the crucible 4.

As the seed crystal 14, a crystal of the same or the same type as a crystal body to be produced is used. For example, if the crystal body to be produced is a YAG crystal (main component) doped with an M element (accessory component), a YAG single crystal (Y₃Al₅O₁₂) containing no additives or the like is used. If the crystal body to be produced is a LuAG crystal body (main component) doped with an M element, a LuAG single crystal (Lu₃Al₅O₁₂) containing no additives or the like is used.

A material of the seed crystal holding jig 12 is not particularly limited, but the seed crystal holding jig 12 is preferably made of dense alumina or the like, which has little influence at an operating temperature of around 1900° C. A shape and a size of the seed crystal holding jig 12 are not particularly limited, but a rod shape having a diameter so that the jig does not come into contact with the refractory furnaces 6 is preferred.

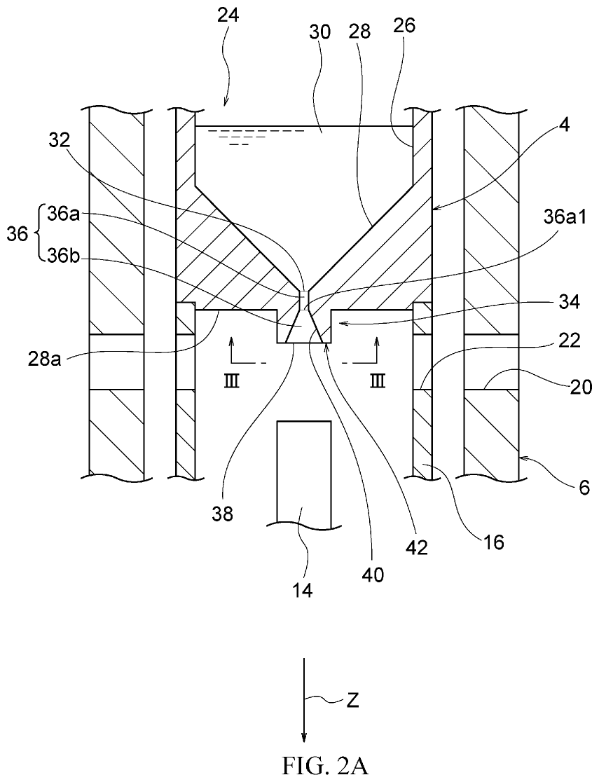

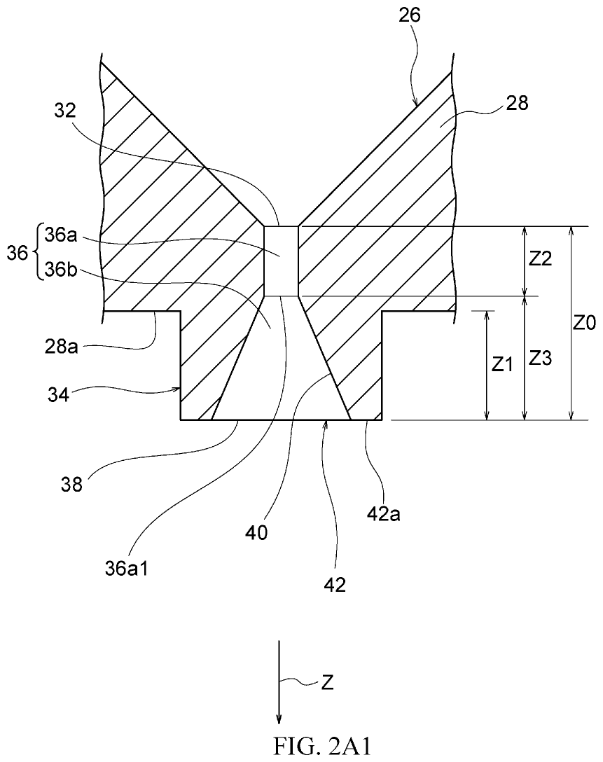

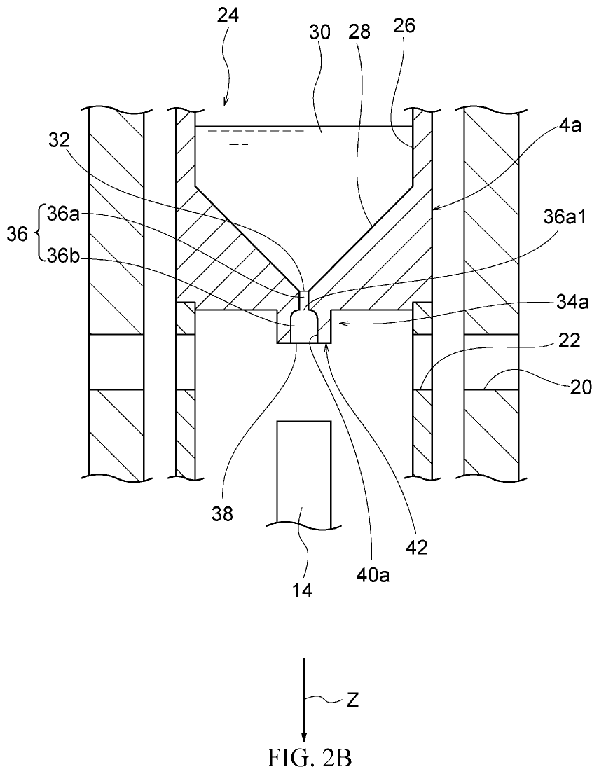

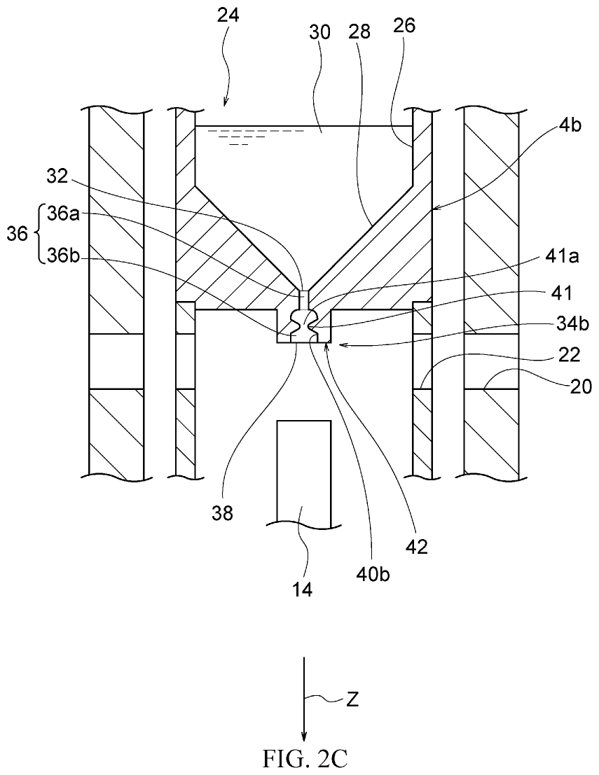

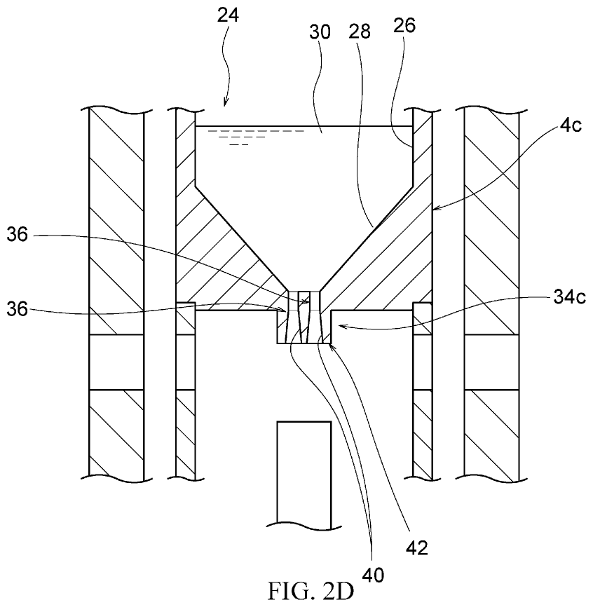

As shown in FIG. 2A, a cylindrical after-heater 16 is installed on an outer periphery of a lower end of the crucible 4. The after-heater 16 is formed with an observation window 22 at the same position as the observation window 20 of the refractory furnace 6. The after-heater 16 is used by being connected to the crucible 4, and is arranged so that a die outlet 38 of a die portion 34 of the crucible 4 is located in an inner space of the cylindrical after-heater 16, so as to heat the melt drawn from the die portion 34 and the die outlet 38. The after-heater 16 is made of, for example, the same material as the crucible 4 (it does not have to be the same). When the after-heater 16 is induced and heated by the high frequency coil 10 similar to the crucible 4, radiant heat is generated from an outer surface of the after-heater 16, and an inside of the after-heater 16 can be heated.

Although not shown, the crystal growth equipment 2 includes a decompression unit for decompressing an inside of the refractory furnace 6, a pressure measuring unit for monitoring the decompression, a temperature measuring unit for measuring a temperature of the refractory furnace 6, and a gas supply unit for supplying an inert gas to the inside of the refractory furnace 6.

A material of the crucible 4 is preferably iridium, rhenium, molybdenum, tantalum, tungsten, platinum, or an alloy thereof for reasons such as a high melting point of the crystal. The crucible 4 may be made of carbon. It is more preferable to use iridium (Ir) as the material of the crucible 4 in order to prevent foreign substances from being mixed into the crystal due to oxidation of the material of the crucible 4.

When a substance having a melting point of 1500° C. or lower is targeted, Pt can be used as the material of the crucible 4. When Pt is used as the material of the crucible 4, crystal growth in atmosphere is possible. When a substance having a high melting point exceeding 1500° C. is targeted, Ir or the like is used as the material of the crucible 4, and therefore the crystal growth is preferably carried out in an inert gas atmosphere such as Ar. A material of the refractory furnace 6 is not particularly limited, but alumina is preferred from viewpoints of heat retention, operating temperature, and prevention of impurities from being mixed into the crystal.

Next, the crucible 4 used in the method for producing a crystal body according to the present embodiment will be described in detail. As shown in FIG. 2A, the crucible 4 according to the present embodiment includes a melt storage portion 24 for storing a melt 30, which is a raw material of the crystal, and the die portion 34 for controlling a shape of the crystal, and the melt storage portion 24 and the die portion 34 are integrally formed. When the crucible 4 is large, a plurality of members may be joined in a middle of a longitudinal direction of the melt storage unit 24 to configure the crucible 4.

In the present embodiment, the crucible 4 is used for a μ-PD method. The die portion 34 is located below the melt storage portion 24 in a vertical direction, and the melt 30 stored in the melt storage portion 24 is drawn from the die outlet 38, which is formed in a lower end surface 42 of the die portion 34, by the seed crystal 14 downward in the vertical direction.

The melt storage portion 24 includes a cylindrical side wall 26 and a bottom wall 28 continuously formed with the side wall 26. A certain amount of the melt 30 can be stored in the melt storage portion 24 by an inner surface of the side wall 26 and an inner surface of the bottom wall 28. A storage portion outlet 32 is formed at a substantially central portion of the bottom wall 28. The storage portion outlet 32 communicates with a die flow path 36 formed at the die portion 34. The die flow path 36 will be described later.

The inner surface of the bottom wall 28 is a reverse-tapered inclined surface whose inner diameter decreases downward, and the melt 30 in the melt storage portion 24 can easily flow toward the storage portion outlet 32. An outer surface of the bottom wall 28 is preferably flush with an outer surface of the side wall 26, and is more preferably flush with the outer surface of the after-heater 16. A lower surface 28a of the bottom wall 28 is a flat plane substantially perpendicular to a flow direction (also referred to as a drawing direction or a pulling down direction) Z of the melt 30, and the after-heater 16 is connected to an outer peripheral portion thereof.

At least a part of the die portion 34 is formed to protrude downward at a substantially central portion of the lower surface 28a of the bottom wall 28. As shown in FIG. 2A1, the lower end surface 42 of the die portion 34 protrudes from the lower surface 28a of the bottom wall 28 at a predetermined distance Z1. The die outlet 38 formed at a substantially central portion of the lower end surface 42 of the die portion 34 and the storage portion outlet 32 formed at the substantially central portion of the bottom wall 28 are connected via the die flow path 36 formed at the die portion 34.

In the present embodiment, the die flow path 36 includes an introduction portion 36a whose inlet is the storage portion outlet 32, and a flow path main body portion 36b communicating with the introduction portion 36a, in which an outlet of the flow path main body portion 36b is the die outlet 38. The die flow path 36 may not include the introduction portion 36a, and may have only the flow path main body portion 36b, but it is preferable that the die flow path 36 includes the introduction portion 36a.

In the present embodiment, the introduction portion 36a may have a flow path cross-sectional area (a cross-sectional area perpendicular to the flow direction) that changes along the flow direction, but preferably, the introduction portion 36a is a straight body portion having a substantially constant flow path cross-sectional area along the drawing direction Z. In the present embodiment, the term “substantially constant” means that the cross-sectional area may be changed to some extent, but the cross-sectional area is less changed than a divergent portion 40 formed at the flow path main body portion 36b. A change in the cross-sectional area is preferably within approximately ±10%, and more preferably within ±5%. In the introduction portion 36a, the flow path may be slightly expanded or slightly narrowed from the storage portion outlet 32 toward the flow path main body portion 36b.

In the present embodiment, a narrow portion 36a1 is formed at the introduction portion 36a (including the storage portion outlet 32, a middle of the introduction portion 36a, or a boundary between the introduction portion 36a and the flow path main body portion 36b). When the introduction portion 36a is a straight body portion, the narrow portion 36a1 is formed at a middle of the straight body portion, the storage portion outlet 32, or the boundary between the introduction portion 36a and the flow path main body portion 36b at a portion where the flow path cross-sectional area is minimum. Since the narrow portion 36a1 is formed at the introduction portion 36a, it becomes easy to adjust a flow rate of the melt stored in the storage portion 24 passing through the die flow path 36, the melt can be drawn from the die outlet 38 at a stable speed, and uniformity of a composition of the crystal (particularly uniformity in the drawing direction) is improved.

According to the present embodiment, the narrow portion 36a1 is a portion in the die flow path 36 whose flow path cross-sectional area is smaller than an opening area of the die outlet 38, and having a flow path cross-sectional area equal to or smaller than the opening area on an upstream side thereof and smaller than the opening area on a downstream side thereof along the drawing direction Z. When two or more narrow portions 36a1 are present along the die flow path 36, the narrow portion closest to the die outlet 38 is the narrow portion 36a1 according to the present embodiment.

For example, in the present embodiment, as shown in FIG. 2A1, since the introduction portion 36a is the straight body portion, the narrow portion 36a1 is formed at the middle of the introduction portion 36a, the storage portion outlet 32, or the boundary between the introduction portion 36a and the flow path main body portion 36b.

In the present embodiment, the flow path main body portion 36b includes the divergent portion 40 whose flow path cross-sectional area increases from the narrow portion 36a1 toward the die outlet 38 along the pulling down direction Z. In the present embodiment, the divergent portion 40 is formed in a tapered shape in which the flow path cross-sectional area gradually increases from the narrow portion 36a1 of the introduction portion 36a toward the die outlet 38.

A length Z2 of the introduction portion 36a along the drawing direction Z is preferably 0 mm to 5 mm, and more preferably 0.5 mm to 2 mm. Since the narrow portion 36a as the straight body portion is formed, it becomes easy to adjust the flow rate of the melt stored in the storage portion 24 passing through the die flow path 36, the melt can be drawn from the die outlet 38 at a stable speed, and the uniformity of the composition of the crystal (uniformity in the drawing direction) is improved.

A length Z3 of the flow path main body portion 36b along the drawing direction Z is determined by, for example, a relation with a total length Z0 (=Z2+Z3) of the die flow path 36, and a ratio (Z3/Z0) is preferably 0.1 to 1, more preferably 0.2 to 0.8, and particularly preferably 0.3 to 0.7. Alternatively, the length Z3 of the flow path main body portion 36b along the drawing direction Z is preferably 1 mm to 5 mm, and more preferably 1.5 mm to 2.5 mm.

The length Z3 of the flow path main body portion 36b along the drawing direction Z may be the same as or different from the distance Z1 from the lower surface 28a of the bottom wall 28 to the lower end surface 42 of the die portion 34. The distance Z1 from the lower surface 28a of the bottom wall 28 to the lower end surface 42 of the die portion 34 along the drawing direction Z is preferably determined so that the melt drawn from the die outlet 38 does not adhere to the lower surface 28a of the bottom wall 28, and is, for example 1 mm to 2 mm.

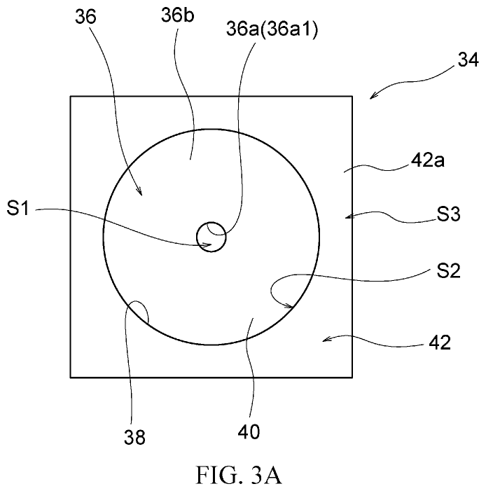

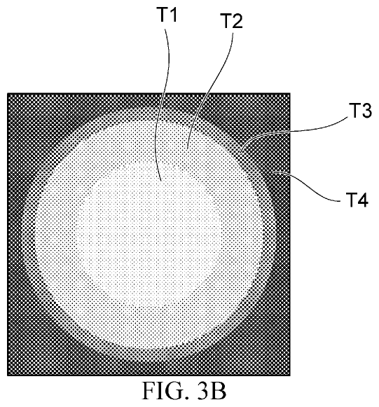

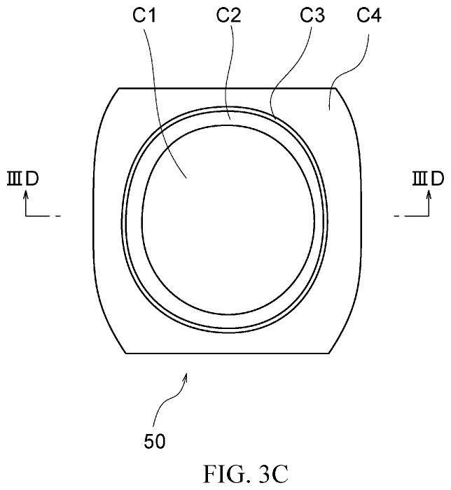

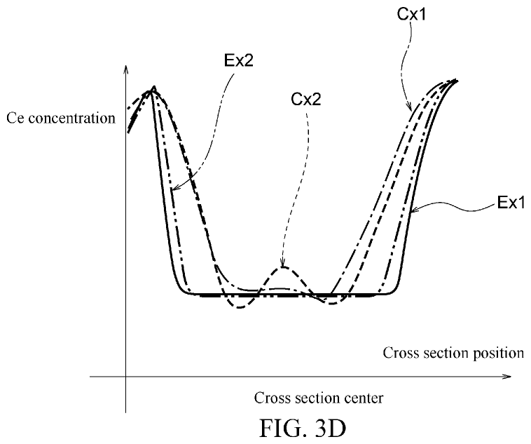

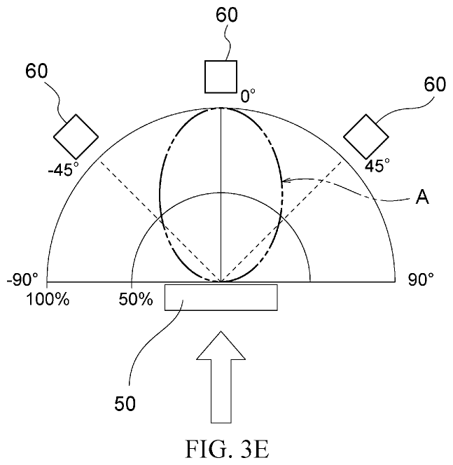

As shown in FIG. 3A, on the lower end surface 42 of the die portion 34, a flat end peripheral surface 42a that is substantially perpendicular to the drawing direction Z (see FIG. 2A) is formed around the die outlet 38. The end peripheral surface 42a is formed between an outer shape of the lower end surface 42 of the die portion 34 and an outer shape of the die outlet 38.

A ratio (S2/(S2+S3)) of an opening area S2 (area perpendicular to the drawing direction Z) of the die outlet 38 to a sum of an area S3 (area perpendicular to the drawing direction Z) of the end peripheral surface 42a and the S2 is preferably 0.10 to 0.95, and more preferably 0.5 to 0.90. A ratio (S2/S1) of the opening area (S2) of the die outlet 38 to a flow path cross-sectional area (S1) of the narrow portion 36a1 is preferably 3 to 3000, and more preferably 10 to 2000. In the present embodiment, the flow path cross-sectional area (S1) of the narrow portion 36a1 is the same as the flow path cross-sectional area of the introduction portion 36a, which is the straight body portion, and the area (S1) is determined so that a speed of the melt drawn from the die outlet 38 of the die flow path 36 and the like is constant, and is preferably 0.008 mm² to 0.2 mm².

In the present embodiment, the outer shape of the lower end surface 42 of the die portion 34 is rectangular according to a cross-sectional (cross section perpendicular to the pulling down direction Z) shape of an obtained crystal body, and a shape of the die outlet 38 is circular but is not limited thereto. For example, the outer shape of the lower end surface 42 of the die portion 34 may also be a circle, a polygon, an ellipse, or any other shape according to the cross-sectional shape of the obtained crystal body. A cross-sectional shape of the die outlet 38 is also not limited to a circle, but may be a polygon, an ellipse, or any other shape. Cross-sectional shapes of the introduction portion 36a and the flow path main body portion 36b are also not limited to a circle, but may be a polygon, an ellipse, or any other shape. The cross-sectional shape of the introduction portion 36a and the cross-sectional shape of the flow path main body portion 36b may be the same or different, but are preferably the same.

The crucible 4 used in the method according to the present embodiment shown in FIG. 1 is preferably used in the μ-PD method or the like. The raw material charged into the melt storage portion 24 of the crucible 4 is heated by the main heater 10 or the like to become the melt 30 shown in FIG. 2A, and is drawn by the seed crystal 14 from the die outlet 38 through the die flow path 36 of the die portion 34, and by pulling down the seed crystal 14, the crystal is grown to obtain the crystal body.

(Method for Producing Crystal Body)

Hereinafter, the method for producing a crystal body of the present embodiment will be described. According to the method of the present embodiment, first, the raw material of the crystal body to be obtained is charged into the melt storage portion 24 of the crucible 4, and the inside of the furnace is replaced with an inert gas such as N₂ or Ar. Next, the crucible 4 is heated by the induction heating coil (high frequency coil for heating) 10 while allowing the inert gas to flow in, and the raw material is melted to obtain a melt.

By heating the melt storage portion 24, the raw material melts in the melt storage portion 24 to become the melt 30, and the melt 30 is guided from the storage portion outlet 32 of the die portion 34 to the die flow path 36. The melt 30 guided to the die flow path 36 passes through the introduction portion 36a and the flow path main body portion 36b, and comes into contact with an upper end of the seed crystal 14 at the die outlet 38. In a process from the introduction portion 36a to the die outlet 38 via the flow path main body portion 36b, the melt 30 passes from the narrow portion 36a1 to the divergent portion 40, and from the die outlet 38 toward the upper end of the seed crystal 14.

Around this time, the after-heater 16 is also activated to heat the vicinity of the die portion 34. A crystal growth rate is manually controlled together with temperatures while observing a state of a solid-liquid interface using a CCD camera or a thermo camera. By moving the induction heating coil 10, a temperature gradient can be selected in a range of 10° C./mm to 100° C./mm. A growth rate of the single crystal can also be selected in a range of 0.01 mm/min to 30 mm/min.

The seed crystal is lowered until the melt in the crucible 4 does not come out, and after the seed crystal is separated from the crucible 4, the single crystal is cooled so as not to crack. By making a steep temperature gradient below the crucible 4 and the after-heater 16 in this way, it is possible to increase a drawing speed of the melt. During the above-mentioned crystal growth and cooling, the inert gas is kept flowing into the refractory furnaces 6 under the same conditions as during heating. It is preferable to use an inert gas such as N₂ or Ar for an atmosphere inside the furnaces.

By adopting the method of the present embodiment, the temperature of the melt pulled down by the seed crystal 14 from the die outlet 38 becomes substantially uniform, particularly in a plane perpendicular to the pulling down direction Z.

By using the method according to the present embodiment, a concentration distribution of a composition (containing an M component as an activator) in the crystal body grown from the die outlet 38 is substantially uniform particularly in the plane perpendicular to the pulling down direction Z, and is also substantially uniform in a plane parallel to the pulling down direction Z. When Ce:YAG is to be produced for example, by using the apparatus 2 of the present embodiment, a crystal body Ce:YAG in which an activator such as Ce is uniformly dispersed can be obtained.

That is, in the present embodiment, the melt 30 from the melt storage portion 24 of the crucible 4 passes through the narrow portion 36a1 provided in the introduction portion 36a of the die flow path 36, then passes through the divergent portion 40 from the narrow portion 36a1 toward the die outlet 38, and is pulled down from the die outlet 38 together with the seed crystal 14. With such a configuration, the uniformity of the temperature distribution of the melt drawn by the seed crystal (particularly the uniformity along the plane perpendicular to the drawing direction of the melt) and the uniformity of the composition of the obtained crystal body are improved. Particularly, an area of a uniform region of the M component in a cross section of the crystal body increases.

In the present embodiment, since the narrow portion 36a1 is formed at the introduction portion 36a, it becomes easy to adjust the flow rate of the melt stored in the storage portion 24 passing through the die flow path 36, the melt can be drawn from the die outlet 38 and then crystallized at a stable speed, and the uniformity of the composition of the crystal body (particularly uniformity in the drawing direction) is also improved.

In the present embodiment, since the flat end peripheral surface 42a that is substantially perpendicular to the drawing direction Z of the melt 30 is provided at the lower end surface 42 of the die portion 36 around the die outlet 38, an outer peripheral surface shape of the crystal body obtained by using the crucible 4 can be easily controlled. Furthermore, in the present embodiment, the ratio (S2/(S2+S3)) of the opening area (S2) of the die outlet 38 to the sum of the area (S3) of the end peripheral surface 42a and the S2 is set within the predetermined range, and the ratio (S2/S1) of the opening area (S2) of the die outlet 38 to the flow path cross-sectional area (S1) of the narrow portion 36a1 is also set within the predetermined range. With such configurations, the uniformity of the temperature distribution of the melt drawn by the seed crystal and the uniformity of the composition of the obtained crystal body are further improved.

(Single Crystalline Phosphor)

A single crystalline phosphor 50 shown in FIG. 3C is obtained by the above method for producing a crystal body, and contains YAG or LuAG as a main component and at least one element of Ce, Pr, Sm, Eu, Tb, Dy, Tm, and Yb as an accessory component.

The fluophor 50 can be confirmed to be a single crystal by confirming a crystal peak of the single crystal by XRD. In the single crystalline phosphor according to the present embodiment, when a total content of the M element and Lu or a specific element Y, i.e., YAG or LuAG is 100 parts by mole, a content of the M element is preferably 0.7 part by mole or more, more preferably 1.0 part by mole or more, and particularly preferably 1.0 part by mole to 2.0 parts by mole.

In a cross section of the single crystalline phosphor 50 shown in FIG. 3C (cross section substantially perpendicular to the pulling down direction Z shown in FIG. 2A1), a uniform concentration region C1 in which the M element is uniformly distributed is located in a central portion so as to include a center of the cross section. Moreover, a cross-sectional area of the uniform concentration region C1 in the single crystalline phosphor 50 is preferably 0.1 mm² or more, and more preferably 0.2 mm² or more.

In the present embodiment, a cross-sectional shape of the uniform concentration region C1 is substantially circular, but may be rectangular to match the shape of the die outlet 38, or may be in any other shape. The cross section of the single crystalline phosphor 50 as a whole has a rectangular shape, but may also be circular or any other shape. The single crystalline phosphor 50 has a predetermined length in a direction perpendicular to a paper surface in FIG. 3C (the drawing direction Z), and has the same cross-sectional shape as the cross section shown in FIG. 3C along the predetermined length. In the present embodiment, when the predetermined length is at least 5 mm along the drawing direction Z, an area ratio of the uniform concentration region C1 to the cross-sectional area of the cross section of the single crystalline phosphor 50 shown in FIG. 3C is 35% or more, and preferably 40% or more of the whole.

A concentration of the M element is defined as follows. That is, an atomic % of the specific element Y or Lu, which is a representative main component, is defined as β, and an atomic % of the M element is defined as α, and thus α×100/(α+β) is expressed as the concentration of the M element (theoretically, 100 atomic % is an upper limit).

In the present embodiment, in the uniform concentration region C1, the concentration of the M element is within a range of C_{M}±0.07 atomic %, and the uniform concentration region C1 has an area equal to or larger than a predetermined area. The concentration C_{M} of the M element is not particularly limited, but is preferably 0.7 atomic % or more, and more preferably 1.0 atomic % or more. The concentration of the M element can be measured by, for example, an LA-ICP mapping method.

The single crystalline phosphor having such a relatively large cross-sectional size and having the uniform concentration region C1 having an area ratio of a predetermined value or more cannot be obtained in the related art. According to the single crystalline phosphor 50 of the present embodiment, a brightness variation and a fluorescence chromaticity variation are unlikely to occur, so that the single crystalline phosphor 50 is preferably used as particularly a large-scale lighting device, a color tone conversion device for a projector, an in-vehicle headlight, and the like.

In the present embodiment, a ratio of the uniform concentration region in the cross section is used as an index for judging the uniformity of the composition of the crystal. The uniform concentration region refers to an area ratio of a region in which an accessory component corresponding to the activator exists within a predetermined concentration range. Therefore, depending on how the concentration range is taken, a plurality of uniform concentration regions may exist in one cross section.

For example, when an accessory component concentration used as the index is 1.00 atomic % and the concentration range is ±0.07 atomic %, an activator concentration in one uniform concentration region is 0.94 atomic % to 1.07 atomic %. Similarly, when another index is 0.7 atomic % and the concentration range is also ±0.07 atomic %, the activator concentration in the uniform concentration region is 0.64 atomic % to 0.77 atomic %.

In the present invention, an average concentration of the accessory component is used as an index level, and a region having a concentration whose vertical width from the average concentration satisfies 0.07 atomic % indicates a uniform concentration region. In the present invention, the central portion of the cross section means a region including a center of gravity of the cross-sectional shape of the fluophor. For example, when the cross-sectional shape is quadrangular, an intersection of diagonal lines is the center of gravity, and thus a region including the intersection of the diagonal lines is the central portion. The expression “located in a central portion of the cross section” means that a uniform concentration region exists as a region including the central portion.

The uniform concentration region preferably exists continuously. Here, the expression “exists continuously” refers to a state in which the uniform concentration region exists in a single island shape in the cross section, and means a state excluding a state in which a plurality of uniform concentration regions are separately located.

### Second Embodiment

As shown in FIG. 2B, in an apparatus used in a method for producing a crystal body according to the present embodiment, only a configuration of a die portion 34a of a crucible 4a is different from that of the first embodiment. Some of the same portions will be omitted, and different portions will be described in detail below. Portions not described below are the same as in the description of the first embodiment.

In the die flow path 36 of the crucible 4a, a shape of a divergent portion 40a, whose flow path cross-sectional area increases from the narrow portion 36a1 formed at an introduction portion 36a toward the die outlet 38, is not a tapered shape in which the cross-sectional area expands linearly, but a shape in which the cross-sectional area expands in a concave curve. The divergent portion 40a may have a straight body portion having substantially the same cross-sectional area along the pulling down direction Z near the die outlet 38, and it is preferable that the straight body portion is short. In the present embodiment, the shape of the divergent portion 40a may be a shape in which the cross-sectional area expands in a convex curve or another curve, instead of the shape in which the cross-sectional area expands in a concave curve.

Even when a single crystalline phosphor is produced using the crucible 4a according to the present embodiment, a single crystalline phosphor similar to the single crystalline phosphor 50 having the cross section shown in FIG. 3C can be obtained.

### Third Embodiment

As shown in FIG. 2C, in an apparatus used in a method for producing a crystal body according to the present embodiment, only a configuration of a die portion 34b of a crucible 4b is different from that of the first or second embodiment. Some of the same portions will be omitted, and different portions will be described in detail below. Portions not described below are the same as in the description of the first or second embodiment.

A narrow portion 41a is formed at the flow path main body portion 36b in the die flow path 36 of the crucible 4b. When the narrow portion 41a is formed at the flow path main body portion 36b, a divergent portion 40b whose flow path cross-sectional area increases from the narrow portion 41a toward the die outlet 38 is formed. In the present embodiment, an intermediate-expanded portion having a cross-sectional area larger than that of the introduction portion 36a and the narrow portion 41a may be formed between the narrow portion 41a formed at the flow path main body portion 36b and the introduction portion 36a.

The narrow portion 41a corresponds to the narrow portion 36a1 of the first or second embodiment described above. The flow path cross-sectional area S1 thereof has the same relation with the opening area S2 of the die outlet 38. The distance Z3 from the narrow portion 41a to the die outlet 38 has the same relation as in the first or second embodiment described above.

An inner diameter of the introduction portion 36a is preferably equal to or greater than an inner diameter of the narrow portion 41a, but may be smaller as long as the melt 30 can pass through. In the present embodiment, the introduction portion 36a may also be formed with a portion having a flow path cross-sectional area smaller than the opening area of the die outlet 38. However, in the present embodiment, the portion that greatly contributes to the uniformity of the temperature distribution of the melt drawn by the seed crystal 14 is the narrow portion 41a that is a starting point of the divergent portion 40b toward the die outlet 38.

Even when a single crystalline phosphor is produced using the crucible 4b according to the present embodiment, a single crystalline phosphor similar to the single crystalline phosphor 50 having the cross section shown in FIG. 3C can be obtained.

### Fourth Embodiment

As shown in FIG. 2D, in an apparatus used in a method for producing a crystal body according to the present embodiment, only a configuration of a die portion 34c of a crucible 4c is different from those in the first to third embodiments. Some of the same portions will be omitted, and different portions will be described in detail below. Portions not described below are the same as in the descriptions of the first to third embodiments.

In the die portion 34 of the crucible 4c, a plurality of (for example, 2 to 8) die flow paths 36 are formed. Each die flow path 36 has the same configuration as that of any of the first to third embodiments. It is preferable that the plurality of die flow paths 36 (for example, 2 to 8) have the same configuration, but may be different. For example, one of the plurality of die flow paths 36 has the same configuration as the die flow path 36 of the first embodiment, and the others may have the same configuration as the die flow path 36 of the second or third embodiment.

Even when a single crystalline phosphor is produced using the crucible 4c according to the present embodiment, a single crystalline phosphor similar to the single crystalline phosphor 50 having the cross section shown in FIG. 3C can be obtained.

The present invention is not limited to the above embodiments, and various modifications can be made within a scope of the present invention. For example, the crystal produced by using the method for producing a crystal body according to the present invention is not limited to a single crystal YAG or LuAG doped with the M element, and single crystals such as Al₂O₃ (sapphire), GAGG (Gd₃Al₂Ga₃O₁₂), GGG (Gd₃Ga₅O₁₂), and GPS (Gd₂Si₂O₇) are also exemplified. The crystal is not limited to a single crystal, and may be a co-crystal such as YAG-Al₂O₃ or LuAG-Al₂O₃.

### EXAMPLES

Hereinafter, the present invention will be described based on more detailed Examples, but the present invention is not limited to these Examples.

### Example 1

Using the crucible 4 shown in FIG. 1 and FIG. 2A, the single crystalline phosphor 50 (see FIG. 3C) of Ce:YAG (YAG doped with Ce) was produced. An inner diameter of the introduction portion 36a as the straight body portion shown in FIG. 2A was 0.4 mm, and an inner diameter of the die outlet 38 was 4 mm. The length Z2 of the introduction portion 36a shown in FIG. 2A1 was 0.5 mm, and the length Z3 of the flow path main body portion 36b was 2 mm. The cross-sectional area of the single crystalline phosphor 50 having a rectangular cross section shown in FIG. 3C was 2.5 mm×2.5 mm.

The ratio Z3/Z0 (Z0=Z2+Z3) was 0.8 within a preferred range of 0.2 to 0.8 but outside a particularly preferred range (0.3 to 0.7). The ratio (S2/(S2+S3)) of the opening area S2 of the die outlet 38 shown in FIG. 3A (area perpendicular to the drawing direction Z) to the sum of the area S3 of the end peripheral surface 42a (area perpendicular to the drawing direction Z) and the S2 was 0.45 within a preferred range of 0.10 to 0.95, but outside a more preferred range of 0.5 to 0.95.

FIG. 3B shows a temperature distribution of the melt (near the solid-liquid interface) immediately after the melt is drawn from the die outlet 38 of the die portion 34 using the crystal growth equipment 2 according to Example 1. T1, T2, T3, and T4 each represent a temperature of an indicated region. The temperature is lowest in T1 and gradually increases from T2 to T3 to T4. For example, the temperature T1 was 1945° C. to 1953° C.; the temperature T2 was 1953° C. to 1961° C.; the temperature T3 was 1965° C. to 1973° C.; and the temperature T4 was 1973° C. or higher. The temperature distribution was measured by simulation analysis.

As can be seen by comparing FIG. 3A with FIG. 3B, in a portion corresponding to the die outlet 38, an area of the portion where the uniform temperatures T1 and T2 are obtained is large. FIG. 3C shows a concentration distribution of Ce in a cross section of Ce:YAG produced by the crystal growth equipment 2 of Example 1. In FIG. 3C, C1, C2, C3, and C4 represent concentrations of Ce (α×100/(α+0), in which an atomic % of Y is defined as β, and an atomic % of Ce is defined as a in the indicated regions. The concentration is lowest in C1 and gradually increases from C2 to C3 to C4. In Example 1, the concentration C1 was 0.94 atomic % to 1.07 (1.00±0.07) atomic %; the concentration C2 was 1.08 atomic % to 1.22 atomic %; the concentration C3 was 1.23 atomic % to 1.37 atomic %; and the concentration C4 was 1.38 atomic % or more. The concentration distribution was measured by LA (laser ablation)-ICP mapping.

As shown in FIG. 3C, the concentration of Ce in the cross section of the grown Ce:YAG crystal was distributed so as to correspond to the temperature distribution shown in FIG. 3B. Corresponding to the outlet 38 of the die flow path 36 shown in FIG. 3A, an area of a region in which the concentration of Ce was uniform with C1 was large, and a size (occupied area) of a largest uniform concentration region was approximately 43.4% of a total cross-sectional area of the obtained crystal body. The region in which the concentration of Ce was uniform with C1 was located in a central portion including a center in the cross section of the single crystalline phosphor 50.

The concentration distribution of Ce in the cross section of the single crystalline phosphor 50 shown in FIG. 3C is shown by a curve Ex1 in FIG. 3D, which is a graph of a cross-sectional position from the center of the cross section. It was confirmed that a width of a region including the center of the cross section and having a uniform concentration of Ce was wide.

In Example 1, as shown in FIG. 3C, the region in which the concentration of Ce is uniform with C1 (within ±0.07%) is a region close to a circle, so that it is also possible to obtain a crystal body including only the region C1 having a relatively large cross-sectional area and a uniform concentration.

Next, with respect to the obtained single crystalline phosphor 50, a fluorescence at 0° (facing an excitation light incident direction) and 450 (side direction of the fluophor) was measured.

As shown in FIG. 3E, the measurement was performed by emitting a blue monochromatic laser beam (wavelength: 460 nm) having an output of 0.4 W and a spot diameter of 2 mm from a back surface of the fluophor 50 having 2.5 mm square×thickness 0.10 mm, and measuring luminosity at each of a front surface of the fluophor (a facing position 0°) and a position rotated by ±450 from the front surface of the fluophor using a photometer sensor 60.

With respect to measured values obtained by the above measuring method, a ratio between a position showing a maximum luminosity (the position 0°) and the other position (a position tilted 45° from the front surface of the fluophor) was defined as a “fluorescence ratio”. The fluorescence ratio influences a variation in brightness from a light source to each position during use. From this viewpoint, the fluorescence ratio is preferably 80% or more. In Example 1, the fluorescence ratio was 83%. In FIG. 3E, a reference numeral A indicates a fluorescence ratio by angle. Table 1 shows measurement results of the fluorescence ratio.

TABLE 1

| | Area | Fluorescence | Internal |
|---|---|---|---|
| | ratio [%] | ratio [%] at 0° | quantum |
| | of uniform | (facing excitation | yield [%] |
| | concentration | light incident | at excitation |
| | region (Ce | direction) and | light wave- |
| | 1.0 ± 0.07 | 45° (side direction | length of |
| | at %) | of fluophor) | 460 nm |
| Comparative | 5.0% | 20% | 82% |
| Example 2 | | | |
| Comparative | 30.2% | 50% | 94% |
| Example 1 | | | |
| Example 3 | 35.0% | 80% | 100% |
| Example 2 | 38.2% | 81% | 100% |
| Example 1 | 43.4% | 83% | 100% |
| Example 4 | 70.0% | 88% | 100% |

Next, an internal quantum yield [%] of the obtained single crystalline phosphor 50 at an excitation light wavelength of 460 nm was measured. A measuring method is shown below.

For the Ce:YAG single crystal, the internal quantum yield of the single crystalline phosphor 50 was measured using an F-7000 type spectrofluorescence meter (manufactured by Hitachi High-Tech Corporation). An ambient temperature was set to 25° C.; a measurement mode was set to a fluorescence spectrum; an excitation wavelength was set to 460 nm; and a photometric voltage was set to 400 V. Each characteristic was measured by emitting an excitation light from a surface where a high concentration region of an end surface in a lateral direction of the single crystalline phosphor 50 was exposed.

A value obtained by the above measuring method was defined as the internal quantum yield [%]. The internal quantum yield [%] is a value calculated from a ratio of a fluorescence intensity generated from the fluophor to an intensity of the excitation light (blue laser light in Example 1) absorbed by the fluophor, and is an index showing a light color conversion efficiency of the fluophor. From this viewpoint, the internal quantum yield [%] is preferably 100%.

Measurement results are shown in Table 1. As shown in Table 1, the internal quantum yield of a sample in Example 1 was as good as 100%.

### Example 2

A sample of a single crystalline phosphor Ce:YAG was produced in the same manner as in Example 1 except for that shown below. The sample of the single crystalline phosphor Ce:YAG was produced in the same manner as in Example 1 using the same apparatus as in Example 1 except that the crucible 4a shown in FIG. 2B was used.

A single crystalline phosphor having a cross section similar to that of the single crystalline phosphor 50 shown in FIG. 3C was obtained. A region in which a concentration of Ce was uniform with C1 was located in the central portion including the center in the cross section of the single crystalline phosphor 50, and an area ratio thereof was 38.2%.

A concentration distribution of Ce is shown by a curve Ex2 in FIG. 3D, which is a graph of the cross-sectional position from the center of the cross section. In Example 2, it was confirmed that a width of the region including the center of the cross section and having a uniform concentration of Ce was wide as in Example 1.

Next, with respect to the obtained sample, the fluorescence at 0° (facing the excitation light incident direction) and the fluorescence at 450 (the side direction of the fluophor) were measured under the same conditions as in Example 1. Results are shown in Table 1. As shown in Table 1, according to the measurement of the fluorescence of the obtained sample, the fluorescence ratio was as good as 81%.

Next, with respect to the obtained sample, the internal quantum yield [%] at an excitation light wavelength of 460 nm was measured under the same conditions as in Example 1. As shown in Table 1, the internal quantum yield of the obtained sample was as good as 100%.

### Example 3

A single crystalline phosphor Ce:YAG was produced in the same manner as in Example 1 except for that shown below. A sample of the single crystalline phosphor Ce:YAG was produced in the same manner as in Example 1 using the same apparatus as in Example 1 except that the crucible 4b shown in FIG. 2C was used.

A single crystalline phosphor having a cross section similar to that of the single crystalline phosphor 50 shown in FIG. 3C was obtained. A region in which a concentration of Ce was uniform with C1 was located in the central portion including the center in the cross section of the single crystalline phosphor 50, and an area ratio thereof was 35.0%.

Next, with respect to the obtained sample, the fluorescence at 0° (facing the excitation light incident direction) and the fluorescence at 450 (the side direction of the fluophor) were measured under the same conditions as in Example 1. Results are shown in Table 1. As shown in Table 1, according to the measurement of the fluorescence of the obtained sample, the fluorescence ratio was as good as 80%.

Next, with respect to the obtained sample, the internal quantum yield [%] at an excitation light wavelength of 460 nm was measured under the same conditions as in Example 1. As shown in Table 1, the internal quantum yield of the obtained sample was as good as 100%.

### Example 4

A single crystalline phosphor Ce:YAG was produced in the same manner as in Example 1 except for that shown below. As shown below, a sample of the single crystalline phosphor Ce:YAG was produced in the same manner as in Example 1 using the same apparatus as in Example 1 except that values of Z3/Z0 and (S2/(S2+S3)) were changed. In Example 4, Z3/Z0 (Z0=Z2+Z3) was 0.5 within a particularly preferred range (0.3 to 0.7), and (S2/(S2+S3)) was 0.72 within a more preferred range (0.5 to 0.95).

A single crystalline phosphor having a cross section similar to that of the single crystalline phosphor 50 shown in FIG. 3C was obtained. A region in which a concentration of Ce was uniform with C1 was located in the central portion including the center in the cross section of the single crystalline phosphor 50, and an area ratio thereof was 70.0%.

Next, with respect to the obtained sample, the fluorescence at 0° (facing the excitation light incident direction) and the fluorescence at 45° (the side direction of the fluophor) were measured under the same conditions as in Example 1. Results are shown in Table 1. As shown in Table 1, according to the measurement of the fluorescence of the obtained sample, the fluorescence ratio was as good as 88%.

Next, with respect to the obtained sample, the internal quantum yield [%] at an excitation light wavelength of 460 nm was measured under the same conditions as in Example 1. As shown in Table 1, the internal quantum yield of the obtained sample was as good as 100%.

### Comparative Example 1

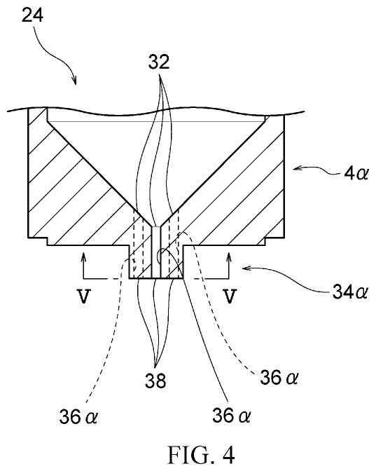

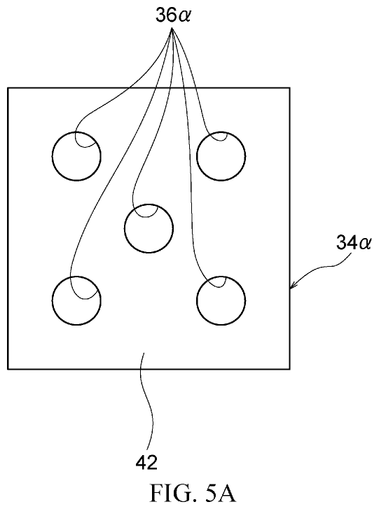

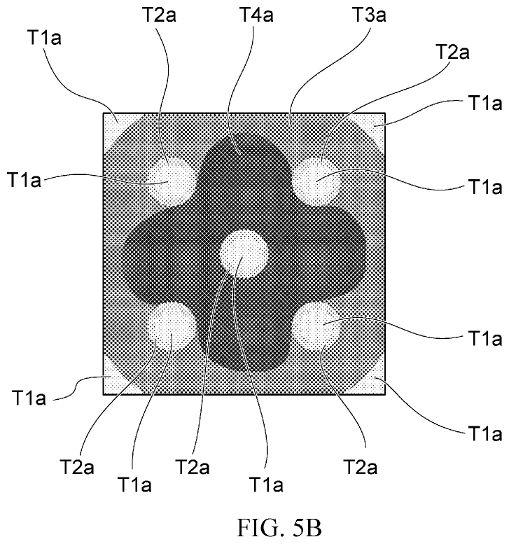

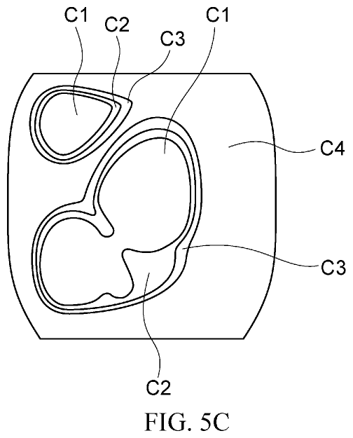

A sample of a single crystalline phosphor Ce:YAG was produced in the same manner as in Example 1 except for that shown below. The single crystalline phosphor Ce:YAG was produced in the same manner as in Example 1 using the same apparatus as in Example 1 except that a crucible 4a in the related art shown in FIGS. 4 and 5A was used.

As shown in FIG. 4, the crucible 4a used in Comparative Example 1 includes the melt storage portion 24 and a die portion 34a. Five storage portion outlets 32 are formed at the central portion of the bottom wall 26 of the melt storage portion 24. Each storage portion outlet 32 communicates with each of five die outlets 38 through a corresponding die flow path 36a. Each of the five die flow paths 36a was a straight body portion having the same flow path cross-sectional area from the storage portion outlet 32 to the die outlet 38, and an inner diameter of each die flow path 36a was the same as the inner diameter of the introduction portion 36a in Example 1.

FIG. 5B shows a temperature distribution of a melt immediately after the melt is drawn from the die outlet 38 of the die portion 34a using the crystal growth equipment according to Comparative Example 1. T1a, T2a, T3a, and T4a each represent a temperature of an indicated region. The temperature is lowest in T1a and gradually increases from T2a to T3a to T4a. For example, the temperature T1a was 1972° C. to 1974° C.; the temperature T2a was 1974° C. to 1976° C.; the temperature T3a was 1976° C. to 1977° C.; and the temperature T4a was 1977° C. or higher.

FIG. 5C shows a concentration distribution of Ce in a cross section of Ce:YAG produced by the crystal growth equipment of Comparative Example 1. In FIG. 5C, C1, C2, C3, and C4 each represent a concentration of Ce in the indicated region. The concentration is lowest in C1 and gradually increases from C2 to C3 to C4. Definitions of the concentrations C1, C2, C3, and C4 are the same as in Example 1.

As shown in FIG. 5C, a size (occupied area) of a region in which the concentration of Ce was uniform with C1 was approximately 30.2% with respect to a total cross-sectional area of the obtained crystal body. A concentration distribution of Ce is shown by a curve Cx1 in FIG. 3D, which is a graph of the cross-sectional position from the center of the cross section.

As shown in FIG. 5C, the region in which the concentration of Ce is uniform with C1 is located in a central portion of the crystal body, but the area thereof is small and a shape thereof is not circular but distorted. Therefore, an amount and a color of fluorescence generated from a surface of the crystal body vary, which makes it difficult to obtain a uniform light emitting state. In Comparative Example 1, a size (occupied area) of a region in which the concentration of Ce is uniform with C4 is large, but a distribution thereof varies in a circumferential direction, which also causes variations in the amount and color of the fluorescence generated from the surface of the crystal body, so that it is difficult to obtain a uniform light emitting state.

Next, with respect to the obtained sample, the fluorescence ratio at 0° (facing the excitation light incident direction) and 45° (the side direction of the fluophor) was measured under the same conditions as in Example 1. Results are shown in Table 1.

As shown in Table 1, according to the measurement of the obtained sample, the fluorescence ratio was 50%, which was insufficient. Next, with respect to the obtained sample, the internal quantum yield [%] at an excitation light wavelength of 460 nm was measured under the same conditions as in Example 1. As shown in Table 1, the internal quantum yield of the obtained sample was 82%. It is presumed that a reason why the internal quantum yield decreases is that crystallinity deteriorates due to extreme segregation of Ce.

### Comparative Example 2

A single crystalline phosphor Ce:YAG was produced in the same manner as in Comparative Example 1 except for that shown below. A sample of the single crystalline phosphor Ce:YAG was produced in the same manner as in Example 1 using the same apparatus as in Example 1 except that in the crucible 4a shown in FIGS. 4 and 5A was used, the five die flow paths 36a was changed to only one die flow path 36a in center.

A concentration distribution of Ce of the obtained sample is shown by a curve Cx2 in FIG. 3D, which is a graph of the cross-sectional position from the center of the cross section. A size (occupied area) of a region including the center of the cross section and having a uniform concentration of Ce was 5% or less.

An average Ce concentration in the cross section of the single crystalline phosphor in Comparative Example 2 was 0.6 atomic %, lower than that in Comparative Example 1.

Next, with respect to the obtained sample, the fluorescence ratio at 0° (facing the excitation light incident direction) and 45° (the side direction of the fluophor) was measured under the same conditions as in Example 1. Results are shown in the above Table 1.

As shown in Table 1, according to the measurement of the obtained sample, the fluorescence ratio was 20%, which was insufficient. Next, with respect to the obtained sample, the internal quantum yield [%] at tan excitation light wavelength of 460 nm was measured under the same conditions as in Example 1. As shown in Table 1, the internal quantum yield of the obtained sample was 94%.

### Example 5

A single crystalline phosphor Ce:YAG was produced in the same manner as in Example 1 except for that shown below. The single crystalline phosphor Ce:YAG was produced in the same manner as in Example 1 using the same apparatus as in Example 1 except that a concentration of an accessory component contained in a Ce raw material powder was changed to adjust a concentration of the accessory component in the uniform concentration region. A size (occupied area) of a region including the center of the cross section and having a uniform concentration of Ce had a concentration region of 35% with respect to the area of the cross section.

An average Ce concentration in the cross section of the obtained sample was 0.1 atomic %, lower than that in Example 3. Next, with respect to the obtained sample (Sample No. 10), the fluorescence ratio at 0° (facing the excitation light incident direction) and 45° (the side direction of the fluophor) was measured under the same conditions as in Example 1. Measurement results are shown in Table 2.

TABLE 2

| | Average | Fluorescence | Internal |
|---|---|---|---|
| | accessory component | ratio [%]of at 0° | quantum |
| | concentration [%] | (facing excitation | yield [%] |
| | in uniform concentration | light incident | at excitation |
| | region when area ratio | direction) and | light wave- |
| | of uniform concentration | 45° (side direction | length of |
| | region is 35% | of fluophor) | 460 nm |
| Example 5 | 0.1 | 80% | 85% |
| Example 6 | 0.7 | 80% | 100% |
| Example 3 | 1.0 | 80% | 100% |

As shown in Table 2, the internal quantum yield was 85%. The fluorescence ratio was 80%.

### Example 6

A single crystalline phosphor Ce:YAG was produced in the same manner as in Example 3 except for that shown below. The single crystalline phosphor Ce:YAG was produced in the same manner as in Example 3 using the same apparatus as in Example 3 except that a concentration of an accessory component contained in a Ce raw material powder was changed to adjust a concentration of the accessory component in the uniform concentration region.

A size (occupied area) of a region including the center of the cross section having a uniform concentration of Ce had a uniform concentration region of 35% with respect to the area of the cross section. An average Ce concentration in the cross section of the single crystalline phosphor in Example 5 was 0.7 atomic %.

Next, with respect to the obtained sample, the fluorescence at 0° (facing the excitation light incident direction) and the fluorescence at 45° (the side direction of the fluophor) were measured under the same conditions as in Example 3.

As shown in Table 2, the internal quantum yield was 100%, equal to that of the fluophor sample in Example 3. The fluorescence ratio was 80%.

### REFERENCE SIGNS LIST

2 crystal growth equipment
4, 4a, 4b, 4c, 4a crucible
6 refractory furnace
8 outer casing
10 main heater
12 seed crystal holding jig
14 seed crystal
16 after-heater
18, 20, 22 observation window
24 melt storage portion
26 side wall
28 bottom wall
28a lower surface
30 melt
32 storage portion outlet
34, 34a, 34b, 34c, 34a die portion
36, 36a die flow path
36a introduction portion
36a1 narrow portion
36b flow path main body portion
38 die outlet
40, 40a, 40b, 40c divergent portion
41 inward convex portion
41a narrow portion
42 end surface
42a end peripheral surface
50 single crystalline phosphor
60 sensor

What is claimed is:

1. A single crystalline phosphor comprising:
a main component comprised of YAG or LuAG; and
an accessory component including at least one of Ce, Pr, Sm, Eu, Tb, Dy, Tm, and Yb, wherein
a uniform concentration region in which the accessory component is uniformly distributed is located in a central portion of a cross section of the single crystalline phosphor, and
an area ratio of the uniform concentration region to the cross section is 35% or more.

2. The single crystalline phosphor according to claim 1, wherein
the uniform concentration region exists continuously and independently in the cross section.

3. The single crystalline phosphor according to claim 1, wherein
an average concentration of the accessory component is 0.7 atomic % or more in the uniform concentration region in the cross section.

4. The single crystalline phosphor according to claim 1, wherein
an average concentration of the accessory component is 1.0 atomic % or more in the uniform concentration region in the cross section.

5. The single crystalline phosphor according to claim 1, wherein
a fluctuation range of a concentration of the accessory component is within a range of ±0.07 atomic % in the uniform concentration region.

6. The single crystalline phosphor according to claim 3, wherein
the main component is comprised of YAG and the accessory component is comprised of Ce.

7. A method for producing a crystal body, comprising the steps of:
guiding a melt of a raw material of a crystal body from a melt storage portion of a crucible to a die flow path;
passing the melt guided to the die flow path through a narrow portion provided in the die flow path;
passing the melt through a divergent portion whose flow path cross-sectional area increases from the narrow portion toward a die outlet; and
pulling down the melt passed through the divergent portion from the die outlet together with a seed crystal so as to crystallize the melt.

8. The method for producing a crystal body according to claim 7, wherein
the crystal body is a single crystalline phosphor.
